(19) United States
(12) Patent Application Publication
(10) Pub. No.: US 2014/0295065 A1
(43) Pub. Date: Oct. 2, 2014

(54) RESIN PROTRUSION FORMING METHOD AND WIRING BOARD MANUFACTURING METHOD

(71) Applicant: FUJITSU LIMITED, Kawasaki-shi (JP)

(72) Inventors: Tomomi Sato, Kawasaki (JP); Tsutomu KOMURO, Kawasaki (JP)

(73) Assignee: FUJITSU LIMITED, Kawasaki-shi (JP)

(21) Appl. No.: 14/194,835

(22) Filed: Mar. 3, 2014

(30) Foreign Application Priority Data
Mar. 28, 2013 (JP) 2013-069447

(51) Int. Cl. H05K 3/00; B29C 59/02; H05K 3/10

(52) U.S. Cl. CPC H05K 3/0014; H05K 3/107; B29C 59/02
USPC 427/98.6; 264/293; 264/139

(57) ABSTRACT

A resin protrusion forming method includes: forming on a substrate a thermal curing resin layer that is in an uncured state; forming a protrusion by pressing a forming mold against the thermal curing resin layer; forming a retaining member that retains a side face of the protrusion; and heating the substrate on which the protrusion and the retaining member have been formed.

### CROSS-REFERENCE TO RELATED APPLICATION

This application is based upon and claims the benefit of priority of the prior Japanese Patent Application No. 2013-069447, filed on Mar. 28, 2013, the entire contents of which are incorporated herein by reference.

### FIELD

The embodiments discussed herein are related to a resin protrusion forming method and a wiring board manufacturing method.

### BACKGROUND

Technology exists in which protrusions (a pattern of recesses and protrusions) are formed on a substrate by transferring a pattern of a mold onto resin that is in an uncured state (a base plate or a base body).

Uncured resin protrusions formed on a substrate are cured by heating the uncured resin to a curing temperature or above, however it is desirable to suppress the protrusions from changing shape when the viscosity of the uncured resin decreases during heating.

### RELATED PATENT DOCUMENTS

Japanese Laid-Open Patent Publication No. 2006-59405

### SUMMARY

According to an aspect of the embodiments, a resin protrusion forming method includes: forming on a substrate a thermal curing resin layer that is in an uncured state; forming a protrusion by pressing a forming mold against the thermal curing resin layer; forming a retaining member that retains a side face of the protrusion; and heating the substrate on which the protrusion and the retaining member have been formed.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1A is a process cross-section illustrating a first process in a wiring board manufacturing method of a first exemplary embodiment.

FIG. 1B is a process cross-section illustrating a process following the process illustrated in FIG. 1A in a wiring board manufacturing method of the first exemplary embodiment.

FIG. 1C is a process cross-section illustrating a process following the process illustrated in FIG. 1B in a wiring board manufacturing method of the first exemplary embodiment.

FIG. 1D is a process cross-section illustrating a process following the process illustrated in FIG. 1C in a wiring board manufacturing method of the first exemplary embodiment.

FIG. 1E is a process cross-section illustrating a process following the process illustrated in FIG. 1D in a wiring board manufacturing method of the first exemplary embodiment.

FIG. 1F is a process cross-section illustrating a process following the process illustrated in FIG. 1E in a wiring board manufacturing method of the first exemplary embodiment.

FIG. 1G is a process cross-section illustrating a process following the process illustrated in FIG. 1F in a wiring board manufacturing method of the first exemplary embodiment.

FIG. 1H is a process cross-section illustrating a process following the process illustrated in FIG. 1G in a wiring board manufacturing method of the first exemplary embodiment.

FIG. 2 is a graph illustrating a qualitative relationship between temperature and viscosity of a thermal curing resin.

FIG. 3 is an enlarged cross-section illustrating the vicinity of a protrusion at the process illustrated in FIG. 1D in a wiring board manufacturing method of the first exemplary embodiment.

FIG. 4A is a process cross-section illustrating part of a process of a wiring board manufacturing method of a Comparative Example.

FIG. 4B is a process cross-section illustrating a process following the process illustrated in FIG. 4A in wiring board manufacturing method of the Comparative Example.

FIG. 4C is a process cross-section illustrating a process following the process illustrated in FIG. 4B in wiring board manufacturing method of the Comparative Example.

FIG. 5A is a process cross-section illustrating part of a process of a wiring board manufacturing method of a second exemplary embodiment.

FIG. 5B is a process cross-section illustrating a process following the process illustrated in FIG. 5A in a wiring board manufacturing method of the second exemplary embodiment.

FIG. 5C is a process cross-section illustrating a process following the process illustrated in FIG. 5B in a wiring board manufacturing method of the second exemplary embodiment.

FIG. 5D is a process cross-section illustrating a process following the process illustrated in FIG. 5C in a wiring board manufacturing method of the second exemplary embodiment.

FIG. 5E is a process cross-section illustrating a process following the process illustrated in FIG. 5D in a wiring board manufacturing method of the second exemplary embodiment.

FIG. 5F is a process cross-section illustrating a process following the process illustrated in FIG. 5E in a wiring board manufacturing method of the second exemplary embodiment.

FIG. 6 is an enlarged cross-section illustrating the vicinity of a protrusion at the process illustrated in FIG. 5D in a wiring board manufacturing method of the second exemplary embodiment.

FIG. 7A is a process cross-section illustrating part of a process of a wiring board manufacturing method of a third exemplary embodiment.

FIG. 7B is a process cross-section illustrating a process following the process illustrated in FIG. 7A in a wiring board manufacturing method of the third exemplary embodiment.

FIG. 7C is a process cross-section illustrating a process following the process illustrated in FIG. 7B in a wiring board manufacturing method of the third exemplary embodiment.

FIG. 7D is a process cross-section illustrating a process following the process illustrated in FIG. 7C in a wiring board manufacturing method of the third exemplary embodiment.

FIG. 7E is a process cross-section illustrating a process following the process illustrated in FIG. 7D in a wiring board manufacturing method of the third exemplary embodiment.

### DESCRIPTION OF EMBODIMENTS

Detailed explanation follows regarding a first exemplary embodiment, with reference to the drawings.

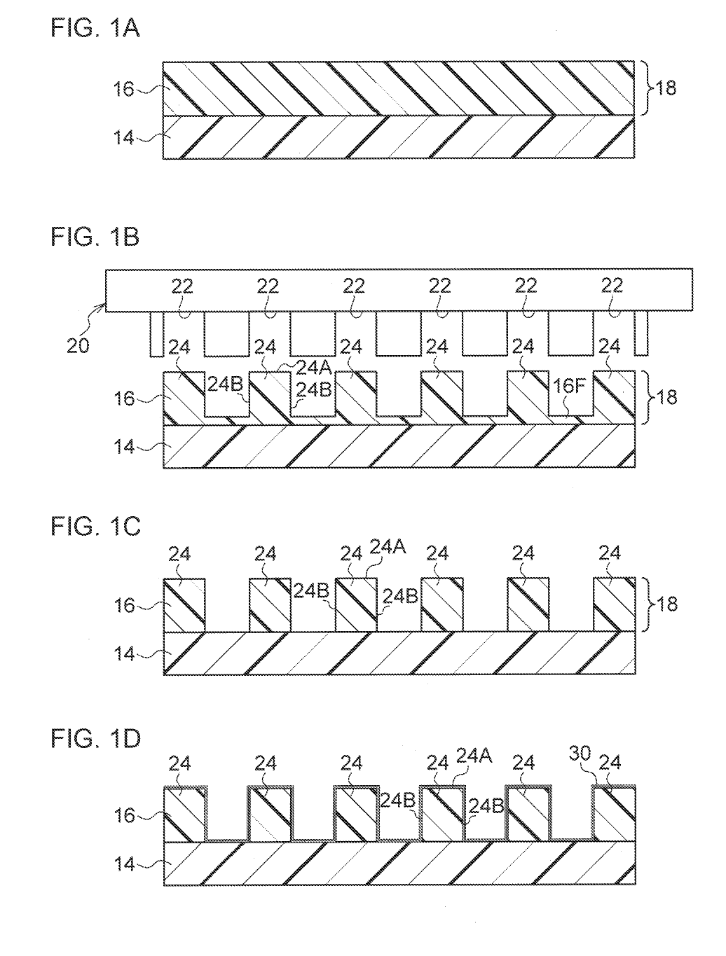

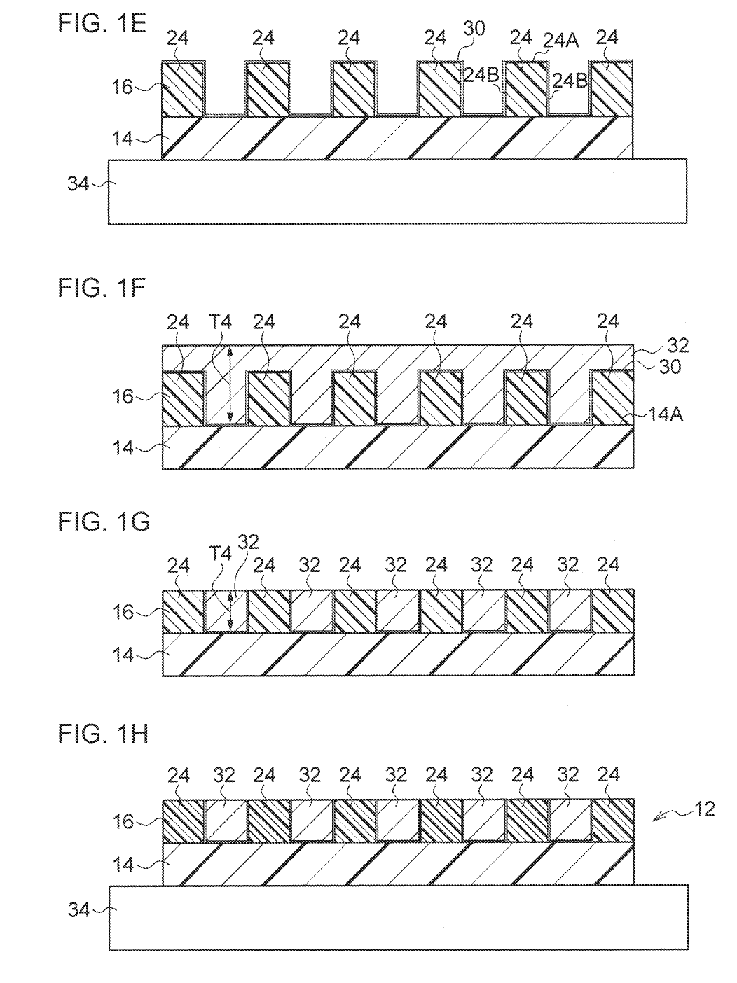

FIG. 1A to FIG. 1H illustrate a sequence of a manufacturing process of a printed substrate 12 using a wiring board manufacturing method of the first exemplary embodiment. The printed substrate 12 is an example of a wiring board. The wiring board manufacturing method includes a resin protrusion forming method as part of the process.

As illustrated in FIG. 1A, in the wiring board manufacturing method of the first exemplary embodiment, firstly an uncured thermal curing resin 16 with insulating properties is adhered or coated onto a substrate 14 at a specific thickness to form an insulating layer 18. The insulating layer 18 is an example of a thermal curing resin layer. Note that the substrate 14 is formed in a plate shape or a film form from for example a resin with insulating properties that is in a cured state (for example a phenol resin or an epoxy resin). The thermal curing resin 16, however, may employ for example an epoxy thermal curing resin.

As illustrated in FIG. 1B, a forming mold 20 set at a specific temperature is pressed against the insulating layer 18 on the opposite side to the substrate 14 in an uncured state of the insulating layer 18, thus forming a specific insulation pattern including plural protrusions 24. The forming mold 20 is formed with recesses 22 at positions corresponding to the respective protrusions 24. In the first exemplary embodiment, the respective protrusions 24 include side faces 24B that are orthogonal to the substrate 14, and an apex face 24A positioned on the opposite side of the insulating layer 18 to the substrate 14. The protrusions 24 are of rectangular cross-section profile. As will be described later, the protrusions 24 are portions that serve as insulating portions between wiring in the printed substrate 12 (see FIG. 1H). The cross-section profile of the protrusions 24 is not limited to a rectangular shape, and may be a square shape or a trapezoidal shape.

Note that there is no limitation of the forming method of the specific pattern of plural protrusions 24 on the substrate 14 to that described above, and for example unwanted portions may be removed by a technique such as etching after performing masking. In the method illustrated in FIG. 1B (also referred to as “imprint”), the plural protrusions 24 are formed by the action of pressing the forming mold 20 against the insulating layer 18. Very fine recesses 22 can easily be formed simply by reducing the inner dimension width of the corresponding recesses 22 even when the protrusions 24 are of narrow width.

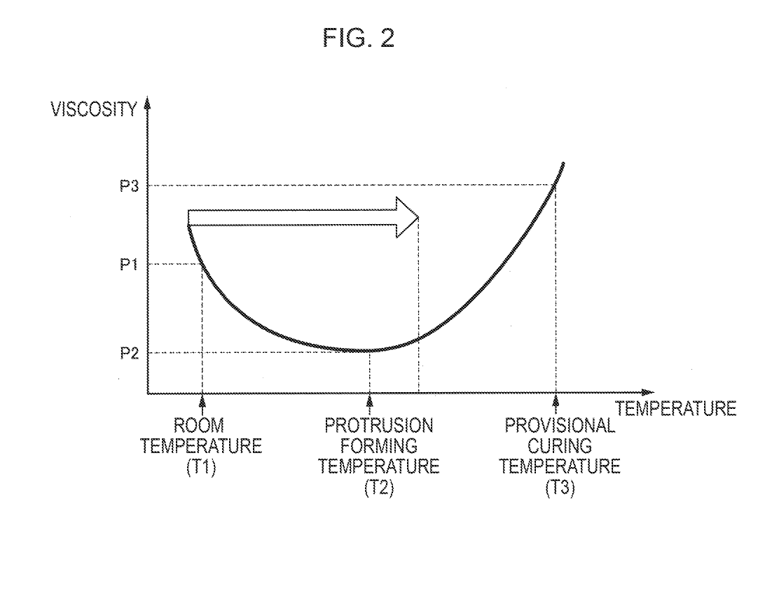

FIG. 2 illustrates a qualitative relationship between temperature and viscosity of the thermal curing resin 16. The thermal curing resin 16 has a specific viscosity P1 at room temperature T1, however the viscosity decreases as temperature rises, with the viscosity becoming minimum (viscosity P2) at a temperature T2. When the temperature rises further and exceeds the temperature T2, the viscosity increases. When forming the plural protrusions 24 with the forming mold 20, the heated forming mold 20 is for example pressed against the thermal curing resin 16, and the temperature of the thermal curing resin 16 is raised to the vicinity of the temperature T2, such that the protrusions 24 are formed in a state of reduced viscosity.

Next, as illustrated in FIG. 1C, surface roughening treatment is performed on the thermal curing resin 16 that has been formed with the plural protrusions 24, and processing is performed to remove film form resin 16F that remains on a wiring face 14A between the protrusions 24 as required. Specific examples of such processing include exposing the thermal curing resin 16 to a specific etching gas according to the type of thermal curing resin 16. An example of etching gas that may be employed is for example a gas mixture of carbon tetrafluoride, CF₄, and argon when an epoxy thermal curing resin is employed as the thermal curing resin 16.

As illustrated in FIG. 1D, a plating base 30 is formed so as to continuously cover the surfaces of the side faces 24B and the apex faces 24A of the protrusions 24 and the wiring face 14A between the protrusions 24. The plating base 30 forms an undercoat layer (plating undercoat layer) during the application of plating 32 to the wiring face 14A side of the substrate 14. In the present exemplary embodiment, electroplating is performed as the plating process. The plating base 30 forms a metal thin film that imparts the surface of the protrusions 24 and the substrate 14 with conducting properties when plating 32 is being applied.

Examples of methods for forming the plating base 30 include vacuum deposition and sputtering. Vacuum deposition and sputtering are methods (known as dry processes) in which the plating base 30 material is adhered to the substrate 14 and the protrusions 24 in a vacuum or in a gas. Accordingly, there is little corrosion of the thermal curing resin 16, unlike when using methods (known as a wet processes) in which the plating base 30 material is adhered whilst immersed in a solution.

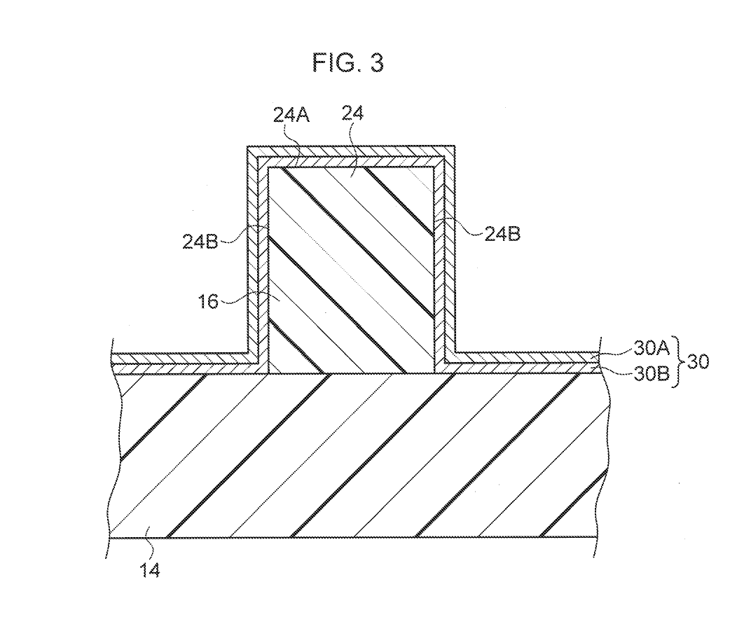

The structure of the plating base 30 may be a single layer structure with only a main component layer 30A employing the same metal as the metal that is employed in plating (for example copper, Cu). As illustrated in detail in FIG. 3, the plating base 30 may also have a double layer structure including, in addition to the main component layer 30A, a close contact layer 30B interposed between the main component layer 30A and the substrate 14 or the thermal curing resin 16. By providing the close contact layer 30B, close contact properties between the substrate 14 and the protrusions 24 and the main component layer 30A can be enhanced. The material of the close contact layer 30B may employ for example titanium Ti. The thickness of the plating base 30 is for example 1 μm or below.

Regardless of the configuration employed, the plating base 30 is in contact with at least the side faces 24B of the protrusions 24. The plating base 30 retains the protrusions 24 from the side face 24B sides even when the viscosity of the thermal curing resin 16 of the protrusions 24 decreases during provisional curing, described later. The plating base 30 is an example of a retaining member.

As illustrated in FIG. 1E, in the thus formed state of the plating base 30 the thermal curing resin 16 is heated to a specific temperature to perform provisional curing. The thermal curing resin 16 is not completely cured in the “provisional curing”, however heat resistance and chemical resistance are raised in comparison to an uncured state. Since water resistance and chemical resistance are raised in the provisionally cured state compared to in the uncured state, the shape of the protrusions 24 can be stably maintained when performing plating and flattening processing (in particular etching), described later.

In the present exemplary embodiment, the thermal curing resin 16 is heated by a hot plate 34 from the opposite side of the substrate 14 to the wiring face 14A. The heating technique employed in provisional curing is not particularly limited, and for example an oven may be employed in place of the hot plate 34, or the hot plate 34 and an oven may be employed in combination.

As can be seen from the graph illustrated in FIG. 2, in order to perform provisional curing of the thermal curing resin 16 the temperature of the thermal curing resin 16 is raised to a level at which the viscosity becomes higher than that at room temperature, for example to a provisional curing temperature T3. The viscosity of the thermal curing resin 16 decreases as the temperature rises, passing through a molten state temperature region (in the vicinity of T2). The viscosity of the thermal curing resin 16 accordingly drops greatly due to thus heating the thermal curing resin 16 to the melting temperature region and above.

In the present exemplary embodiment, the plating base 30 is in contact with the side faces 24B and the apex faces 24A of the protrusions 24, such that the plating base 30 retains the protrusions 24. Accordingly, deformation (collapse) due to the protrusions 24 flowing sideways is suppressed even when the viscosity of the thermal curing resin 16 of the protrusions 24 has decreased. In particular, the portions of the plating base 30 that contact the side faces 24B of the protrusions 24 act as a barrier, stopping flow of the thermal curing resin 16 and effectively suppressing deformation of the protrusions 24.

Specifically, provisional curing of the thermal curing resin 16 may be performed by a 2-step process of for example first heating to 90° C. for about 30 minutes, and then heating to 180° C. for about 30 minutes.

As illustrated in FIG. 1F, after provisional curing of the thermal curing resin 16 (protrusions 24), the plating 32 is formed from the wiring face 14A side of the substrate 14 so as to cover the substrate 14 and the protrusions 24. The portions of the plating 32 between the protrusions 24 form the wiring of the printed substrate 12. Accordingly, copper, Cu, is employed as the material for the plating 32 in the present exemplary embodiment. A thickness T4 of the plating 32 (the height from the wiring face 14A) is at least of a level that covers the plating base 30 on the protrusions 24.

Then, as illustrated in FIG. 1G, flattening processing is performed to flatten the plating 32 on the opposite side to the substrate 14 (the upper side in FIG. 1G). In this flattening processing, the thickness T4 of the plating 32 is thinned to a level that exposes the protrusions 24 at the flattened portions. Specific examples of methods that may be employed for flattening processing include abrasion and etching. The copper, Cu, sites positioned between the protrusions 24 are mutually insulated from each other by the flattening processing, as can be seen in the cross-section illustrated in FIG. 1G, thereby forming a specific wiring pattern on the wiring face 14A.

Moreover, as illustrated in FIG. 1H, the thermal curing resin 16 of the protrusions 24 is heated to a specific temperature to perform main curing. “Main curing” refers to further curing the thermal curing resin 16 that has been “provisionally cured” as described above, and may be achieved by heating to a higher temperature and/or for a longer time than in provisional curing. For example, since in the present exemplary embodiment an epoxy thermal curing resin is employed as the thermal curing resin 16, heating to 180° C. for about 60 minutes may be performed in order to perform main curing. The heating technique employed in main curing may employ for example the hot plate 34 or an oven singly, or may employ a combination of the two.

The printed substrate 12 is thus obtained. The specific wiring pattern is formed on the wiring face 14A of the printed substrate 12.

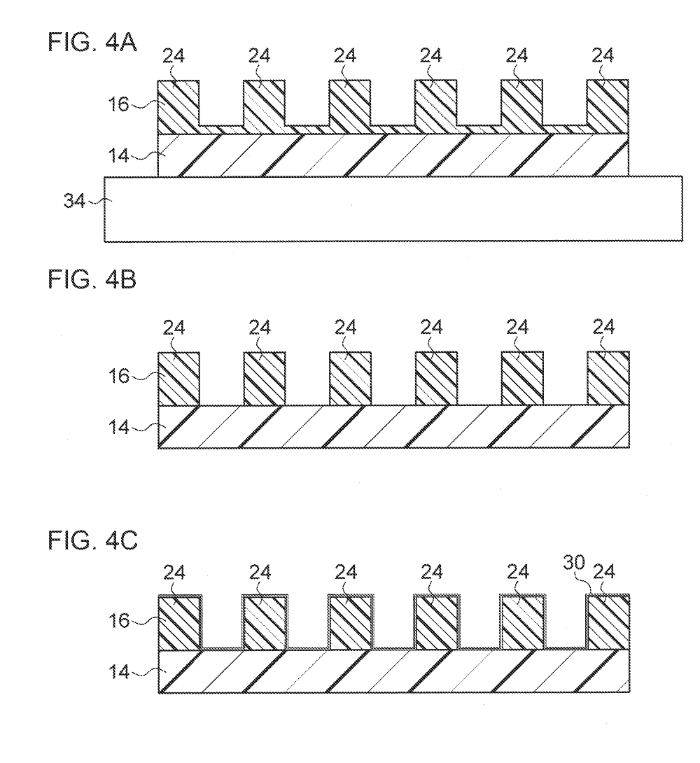

FIG. 4A to FIG. 4C illustrate part of a process of a wiring board manufacturing method of a Comparative Example. As illustrated in FIG. 4A, in the wiring board manufacturing method of the Comparative Example a specific thermal curing resin 16 that is formed with protrusions 24 on a substrate 14 by a forming mold 20 (see FIG. 1B) is provisionally cured using for example a hot plate 34 or an oven prior to forming a plating base. Then as illustrated in FIG. 4B, surface roughening treatment is performed on the thermal curing resin 16, and processing is performed to remove film form resin 16F from between the protrusions 24. Next, as illustrated in FIG. 4C, the plating base 30 is formed so as to continuously cover side faces 24B and apex faces 24A of the protrusions 24 and a wiring face 14A between the protrusions 24. Namely, in the wiring board manufacturing method of the Comparative Example, provisional curing of the thermal curing resin 16 is performed prior to forming the plating base 30. Forming of the plating 32 (see FIG. 1F), flattening of the plating 32 (see FIG. 1G), and main curing of the protrusions 24 (see FIG. 1H) are then performed. That is to say, in the wiring board manufacturing method of the Comparative Example the plating base 30 is formed after provisional curing of the thermal curing resin 16, whereas in the wiring board manufacturing method of the first exemplary embodiment the plating base 30 is formed prior to provisional curing of the thermoset resin 16.

In the Comparative Example, the shape of the protrusions 24 (insulation pattern) after provisional curing may change with respect to the shape of the protrusions 24 prior to provisional curing.

However in the first exemplary embodiment, there is little change in the shape of the protrusions 24 (insulation pattern) after provisional curing with respect to the shape of the protrusions 24 prior to provisional curing. This is thought to be since the plating base 30 in the first exemplary embodiment is formed prior to provisional curing, with the plating base 30 suppressing deformation of the protrusions 24 (the thermal curing resin 16 in a reduced viscosity state) at the side faces 24B and the apex faces 24A (and in particular at the side faces 24B) of the protrusions 24.

Namely, the wiring board manufacturing method of the first exemplary embodiment enables the printed substrate 12 to be manufactured with the protrusions 24 suppressed from changing in shape during provisional curing.

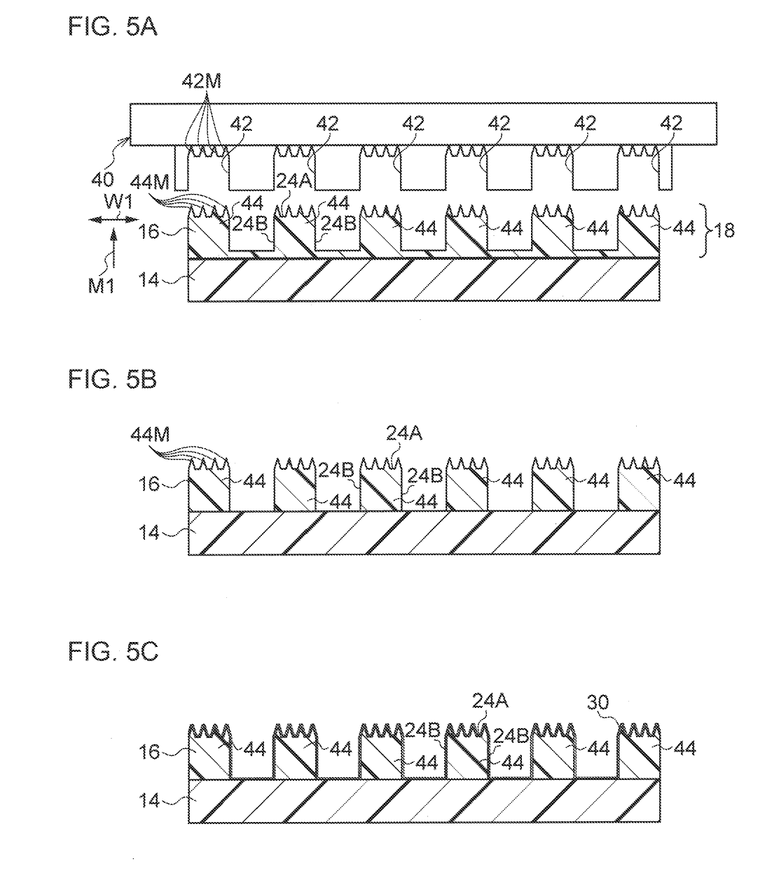

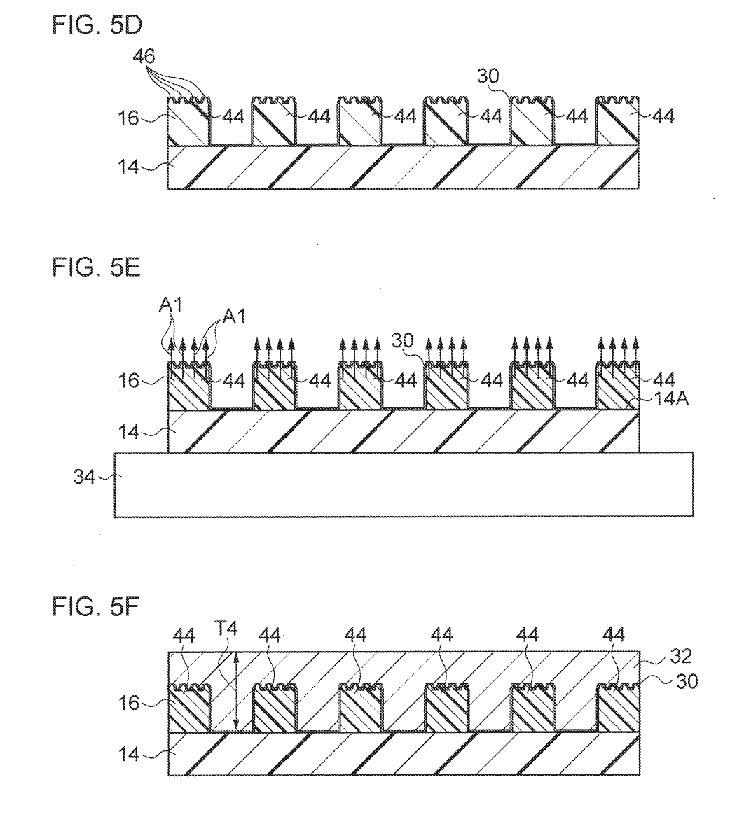

Next, explanation follows regarding a wiring board manufacturing method of a second exemplary embodiment. FIG. 5A to FIG. 5F illustrate part of a process of the wiring board manufacturing method of the second exemplary embodiment. In the second exemplary embodiment, processes that are substantially the same as those of the first exemplary embodiment are omitted from illustration, or employ the drawings for the first exemplary embodiment, as appropriate.

In the wiring board manufacturing method of the second exemplary embodiment, similarly to in the wiring board manufacturing method of the first exemplary embodiment, an uncured thermal curing resin 16 with insulating properties is adhered or coated onto a substrate 14 at a specific thickness, forming an insulating layer 18 (see FIG. 1A).

Next, a forming mold 40 is pressed against the substrate 14 from the opposite side to form a specific insulation pattern with plural protrusions 44. In the wiring board manufacturing method of the second exemplary embodiment, plural fine recesses 42M are formed to bottom faces of recesses 42 of the forming mold 40. Apex faces of the plural protrusions 44 formed using the forming mold 40 are accordingly formed with plural fine projections 44M corresponding to the fine recesses 42M. The fine projections 44M are an example of projection portions.

In the second exemplary embodiment, the fine projections 44M project out in the same direction as the projection direction of the protrusions 44 (the arrow M1 direction), so as to be finer than the protrusions 44. In particular, in the illustrated example, the respective fine projections 44M are configured with tapered shapes (for example circular conical shapes) that become thinner on progression towards the leading ends. The fine projections 44M are disposed in rows at specific separations to each other in the width direction (the arrow W1 direction) and the depth direction (a direction orthogonal to both the arrow M1 and the arrow W1). Note that the projection portions do not have to be finer than the protrusions 44.

The thermal curing resin 16 is thus formed with the fine projections 44M on the apex faces 24A of the protrusions 44. Similarly to in the wiring board manufacturing method of the first exemplary embodiment, face roughening is performed on the surface of the thermal curing resin 16 as illustrated in FIG. 5B, and processing is performed to remove film form resin 16F that remains on the wiring face 14A between the protrusions 44 as required.

As illustrated in FIG. 5C, a plating base 30 is formed so as to continuously cover the surfaces of the side faces 24B and apex faces 24A (including the fine projections 44M) of the protrusions 44 and the wiring face 14A between the protrusions 44.

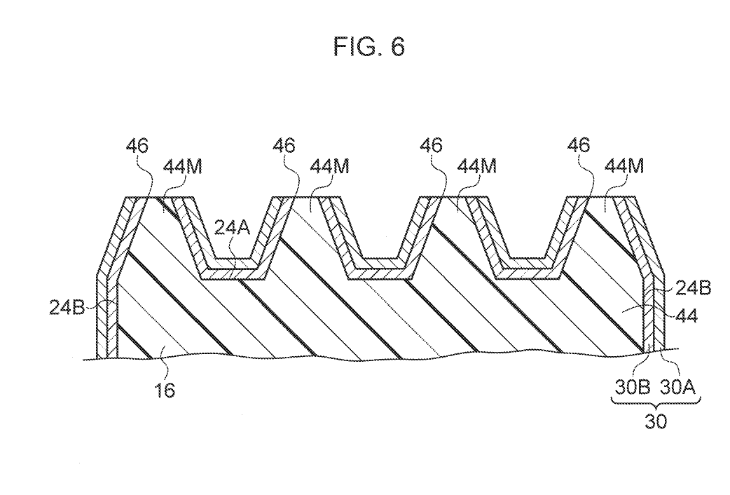

Next in the wiring board manufacturing method of the second exemplary embodiment, as illustrated in FIG. 5D and FIG. 6, the plating base 30 is selectively removed from leading end portions of the fine projections 44M, forming through holes 46 that penetrate the plating base 30 along the thickness direction. Forming the through holes 46 exposes the thermal curing resin 16 at the leading end portions of the fine projections 44M.

Note that etching may be employed as the method for partially removing the plating base 30. Using etching, the plating base 30 can easily be locally removed at the positions of the leading end portions of the fine projections 44M due to the tapered shape of the fine projections 44M.

As illustrated in FIG. 5E, the thermal curing resin 16 is heated to a specific temperature to perform provisional curing in a state in which the through holes 46 are formed in the plating base 30. In the wiring board manufacturing method of the second exemplary embodiment, the plating base 30 is formed with the through holes 46. Gas components arising in the thermal curing resin 16 during provisional curing is released to the outside of the thermal curing resin 16 through the through holes 46 as illustrated by the arrows A1, thereby enabling deformation of the plating base 30 and the protrusions 44 caused by the occurrence of gas components to be suppressed.

Note that similarly to in the wiring board manufacturing method of the first exemplary embodiment, in the wiring board manufacturing method of the second exemplary embodiment the provisional curing may for example employ a method of contacting a hot plate 34 against the opposite side of the substrate 14 to the wiring face 14A, or may employ an oven. In particular, heating slowly by contacting the hot plate 34 against the opposite side to the positions where the through holes 46 are formed (the opposite face to the wiring face 14A) is preferable from the perspective of promoting the release of the gas component arising in the thermal curing resin 16.

Moreover, in the second exemplary embodiment, the plating base 30 contacts the side faces 24B and the apex faces 24A (in particular the side faces 24B) of the protrusions 44. The plating base 30 acts as a barrier stopping the thermal curing resin 16 from flowing, thereby effectively suppressing deformation of the protrusions 24.

As illustrated in FIG. 5F, after provisional curing of the thermal curing resin 16 (protrusions 24) plating is then performed to form plating 32 that covers the substrate 14 and the protrusions 44 from the wiring face 14A side of the substrate 14. A thickness T4 of the plating 32 is at least of a level that covers the plating base 30 of the protrusions 24 (the portions where the through holes 46 are formed).

Moreover, similarly to in the wiring board manufacturing method of the first exemplary embodiment, flattening processing is performed to flatten the plating 32 on the opposite side to the substrate 14 (see FIG. 1G). The thickness T4 of the plating 32 is thinned at the flattened portions so as to expose the protrusions 44. The fine projections 44M are effectively removed in the second exemplary embodiment. The copper, Cu, positioned between the protrusions 44 is mutually insulated by the flattening processing, thereby forming the specific wiring pattern on the wiring face 14A.

Moreover, main curing is performed similarly to in the wiring board manufacturing method of the first exemplary embodiment by heating the thermal curing resin 16 of the protrusions 44 to a specific temperature (see FIG. 1H).

The printed substrate 12 (see FIG. 1H) with the specific wiring pattern formed to the wiring face 14A is thus obtained in the wiring board manufacturing method of the second exemplary embodiment.

In particular, in the wiring board manufacturing method of the second exemplary embodiment, the gas component arising in the thermal curing resin 16 during provisional curing can be released through the through holes 46 formed in the plating base 30. Deformation of the plating base 30 and deformation of the protrusions 24 caused by the gas component that arises in the thermal curing resin 16 can accordingly be effectively suppressed.

In the wiring board manufacturing method of the second exemplary embodiment, the through holes 46 formed in the plating base 30 are an example of “passage portions”, however there is no limitation of the structure of the passage portions to that of the through holes 46. For example, similarly to in the first exemplary embodiment, a portion at which the plating base 30 is removed may be provided at part of a portion contacting the apex face 24A of the protrusions 44 even in a structure in which the fine projections 44M are not formed to the protrusions 44, such that gas components that arise during provisional curing of the thermal curing resin 16 are released through the removed portion.

In the wiring board manufacturing method of the second exemplary embodiment, the passage portion can be formed easily by forming the through holes 46 using etching.

Moreover, etching may be employed to selectively remove the plating base 30 at the leading end portions of the fine projections 44M due to forming the fine projections 44M that are finer than the protrusions 44, thus enabling the through holes 46 to be efficiently formed.

In particular, the benefits of etching the plating base 30 positioned at the leading end portions of the fine projections 44M can be readily obtained due to forming the fine projections 44M with tapered shapes. The through holes 46 can accordingly be formed in a short space of time. Specific examples of tapered shapes of the fine projections 44M are not limited to the circular conical shapes described above, and configuration may be made with pyramidal shapes. Circular conical trapezoidal shapes or pyramidal trapezoidal shapes may also be employed. In the example described above, the fine projections 44M are disposed in rows at specific separations along the width direction (in the arrow W1 direction) and in the depth direction (in a direction orthogonal to both the arrow M1 direction and the arrow W1 direction). The through holes 46 are accordingly dispersed evenly over the apex face 24A.

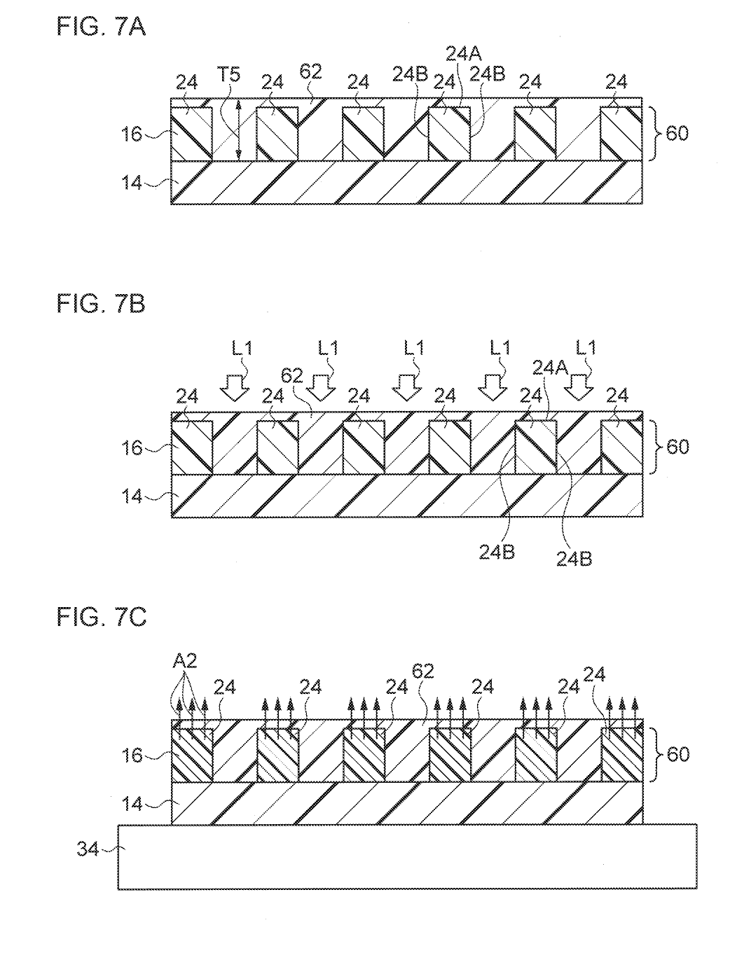

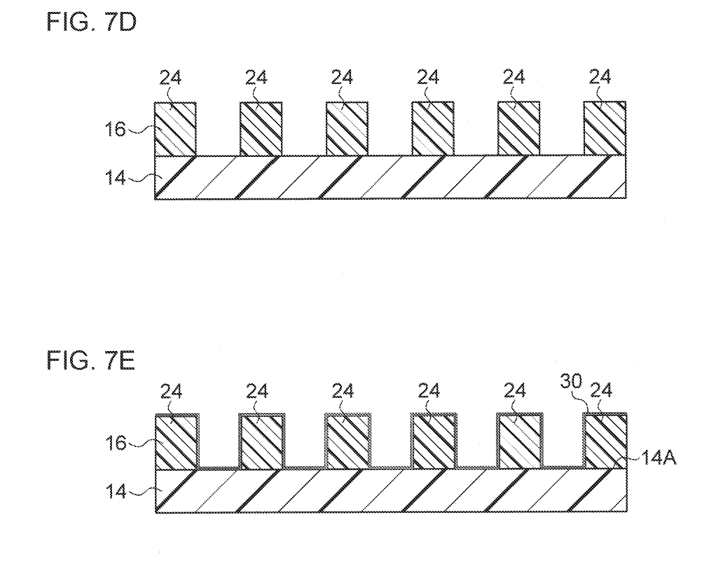

Explanation follows regarding a wiring board manufacturing method of a third exemplary embodiment. FIG. 7A to FIG. 7E illustrate part of a wiring board manufacturing method process of the third exemplary embodiment. In the third exemplary embodiment, processes that are substantially the same as those of the first exemplary embodiment are omitted from illustration, or employ the drawings for the first exemplary embodiment, as appropriate.

In the wiring board manufacturing method of the third exemplary embodiment, similarly to in the wiring board manufacturing method of the first exemplary embodiment, an uncured thermal curing resin 16 with insulating properties is adhered or coated onto a substrate 14 at a specific thickness, forming an insulating layer 18 (see FIG. 1A).

Next, a forming mold 20 set at a specific temperature is pressed against the insulating layer 18 that is in an uncured state from the opposite side to the substrate 14, forming a specific insulation pattern with plural protrusions 24 (see FIG. 1B).

Surface roughening is then performed on the thermal curing resin 16 configured with the specific pattern shape, and processing is performed to remove film form resin 16F that remains on the wiring face 14A between the protrusions 24 as required (see FIG. 1C). The above processes are effectively the same as the processes of the wiring board manufacturing method of the first exemplary embodiment.

As illustrated in FIG. 7A, next in the wiring board manufacturing method of the third exemplary embodiment a retaining resin layer 60 is formed from an uncured photosensitive thermal curing resin 62 so as to cover the side faces 24B and apex faces 24A of the protrusions 24 and also the wiring face 14A between the protrusions 24. A thickness T5 of the retaining resin layer 60 (the height from the wiring face 14A of the substrate 14) is configured as the height of the protrusions 24 or greater, and the retaining resin layer 60 is in contact with the side faces 24B and the apex faces 24A of the protrusions 24. Namely, the retaining resin layer 60 is an example of a retaining member in the wiring board manufacturing method of the third exemplary embodiment.

The photosensitive thermal curing resin 62 is a resin that is cured by exposure to light, however a semi-cured state can be achieved by adjusting the light exposure conditions during light exposure. In the semi-cured state, the heat resistance of the photosensitive thermal curing resin 62 is increased to a level at which the photosensitive thermoset resin 62 does not deform at the provisional curing temperature of the thermal curing resin 16. Gas components are moreover able to pass through the photosensitive thermal curing resin 62 in the semi-cured state. In the semi-cured state, the photosensitive thermal curing resin 62 can be removed from the substrate 14 and the protrusions 24 (thermal curing resin 16) by employing a specific removal agent.

The retaining resin layer 60 of the photosensitive thermal curing resin 62 is exposed to light as illustrated by the arrows L1 in FIG. 7B, thus placing the photosensitive thermal curing resin 62 in the semi-cured state. Namely, the photosensitive thermal curing resin 62 with enhanced heat resistance in the semi-cured state is placed in a state contacting and retaining the side faces 24B and the apex faces 24A of the protrusions 24.

Note that the retaining resin layer 60 may for example be formed by forming the photosensitive thermal curing resin 62 into a thin film form in advance, and then adhering (laminating) the photosensitive thermal curing resin 62 to the substrate 14 and the protrusions 24. Deformation of the protrusions 24 during lamination can be suppressed by employing a material that can be laminated at a lower temperature than the deformation temperature of the thermal curing resin 16. Moreover, thermal curing of the photosensitive thermal curing resin 62 during provisional curing, described later, can be suppressed by employing a photosensitive thermal curing resin 62 with a curing temperature that is high enough that thermal curing does not occur at the provisional curing temperature of the thermal curing resin 16.

Moreover, in the thus formed state of the retaining resin layer 60 of the photosensitive thermal curing resin 62, the thermal curing resin 16 is heated to a specific temperature to perform provisional curing, as illustrated in FIG. 7C. The temperature during provisional curing is lower than the thermal curing temperature of the photosensitive thermal curing resin 62. Curing of the photosensitive thermal curing resin 62 can accordingly be suppressed.

In the wiring board manufacturing method of the third exemplary embodiment, the side faces 24B and the apex faces 24A of the protrusions 24 (in particular the side faces 24B) are contacted by the photosensitive thermal curing resin 62. The photosensitive thermal curing resin 62 acts as a barrier, stopping the thermal curing resin 16 from flowing, thereby enabling deformation of the protrusions 24 to be suppressed.

Gas components are able to pass through the photosensitive thermal curing resin 62 in the semi-cured state. Namely, gas components arising from the thermoset resin 16 during provisional curing passes through the photosensitive thermal curing resin 62 (the retaining resin layer 60) as illustrated by the arrows A2.

After provisional curing of the thermal curing resin 16, the photosensitive thermal curing resin 62 of the retaining resin layer 60 is removed employing a specific removal agent, as illustrated in FIG. 7D.

Then, as illustrated in FIG. 7E, a plating base 30 is formed so as to continuously cover the surfaces of the side faces 24B and apex faces 24A of the protrusions 24 as well as the wiring face 14A between the protrusions 24.

Next, plating 32 is formed to the wiring face 14A side of the substrate 14 (see FIG. 1F), flattening processing is performed to the plating 32 on the opposite side to the substrate 14 (see FIG. 1G), and main curing of the protrusions 24 (the thermal curing resin 16) is performed (see FIG. 1H). The printed substrate 12 with the specific printed wiring pattern formed to the wiring face 14A is thus obtained by the wiring board manufacturing method of the third exemplary embodiment (see FIG. 1H).

In the wiring board manufacturing method of the third exemplary embodiment, the retaining resin layer 60 that is formed as the retaining member is removed. However, in the wiring board manufacturing methods of the first exemplary embodiment and the second exemplary embodiment, the plating base 30 that is employed when the plating 32 is being formed is employed as the retaining member, thereby achieving a simpler manufacturing method since there is no process of removing the retaining member (plating base 30).

Each of the exemplary embodiments described above enables the advantageous effect of suppressing deformation of the protrusions 24 during provisional curing provided that the retaining member (the plating base 30 or the retaining resin layer 60) is disposed so as to be in contact with at least the side faces 24B of the protrusions 24.

The retaining member can suppress deformation of the thermal curing resin 16 of the protrusions 24 towards the apex faces 24A side during provisional curing provided that the retaining member is disposed so as to be in contact with the apex faces 24A as well as the side faces 24B.

In the above description, an example has been given of a method in which curing of the thermal curing resin 16 (the protrusions 24, 44) is performed 2 times (provisional curing and main curing), however there is no need to perform curing 2 times in cases in which 1 time of curing would suffice. Curing may also be performed 3 times or more.

In the above description, examples have been given of wiring board manufacturing methods including a portion of a resin protrusion forming method, however there is no limitation to application of the resin protrusion forming method to wiring board (printed substrate 12) manufacturing methods. Namely, the resin protrusion forming method may be applied in other cases in which deformation of thermal curing resin is suppressed during thermal curing during the formation of protrusions on a substrate from a thermal curing resin. For example, the resin protrusion forming method may be employed as part of a manufacturing method for manufacturing grid structures of various displays, specifically including for example wire grid polarizers, diffraction gratings, and anti-reflective films. There are also cases in which the molded product does not require a plating base. In the first exemplary embodiment and the second exemplary embodiment, the plating base 30 may be removed at an appropriate timing, for example after provisional curing of the protrusions 24. In the third exemplary embodiment, after removal of the retaining resin layer 60 the following process may be performed without forming the plating base.

There is no limitation of wiring boards to the printed substrate 12, and the wiring board may for example be a flexible wiring substrate.

Explanation has been given above regarding exemplary embodiments of the technology disclosed herein, however there is no limitation of the technology disclosed herein to the above description. Obviously various modifications may be implemented within a range not departing from the spirit of the technology disclosed herein.

According to the technology disclosed herein, a protrusion formed on a substrate from a thermal curing resin in an uncured state can be suppressed from changing shape during thermal curing of the protrusion portion.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

All cited documents, patent applications and technical standards mentioned in the present specification are incorporated by reference in the present specification to the same extent as if the individual cited documents, patent applications and technical standards were specifically and individually incorporated by reference in the present specification.

What is claimed is:

1. A resin protrusion forming method comprising:
forming on a substrate a thermal curing resin layer that is in an uncured state;
forming a protrusion by pressing a forming mold against the thermal curing resin layer;
forming a retaining member that retains a side face of the protrusion; and
heating the substrate on which the protrusion and the retaining member have been formed.

2. The resin protrusion forming method of claim 1, wherein the retaining member is a plating undercoat layer that forms an undercoat for plating of the protrusion and the substrate.

3. The resin protrusion forming method of claim 2, wherein the plating undercoat layer is a single layer structure of the same material as the plating.

4. The resin protrusion forming method of claim 2, wherein the plating undercoat layer includes a main component layer of the same material as the plating, and a close contact layer that places the main component layer in close contact with either the substrate or the thermal curing resin layer.

5. The resin protrusion forming method of claim 2, wherein:
the retaining member is formed so as to cover the protrusion that is in the uncured state; and
a through hole is formed in the formed retaining member.

6. The resin protrusion forming method of claim 5, wherein:
the protrusion is configured with a plurality of projection portions formed by pressing the forming mold, which is formed with a plurality of fine recesses, against the thermal curing resin layer; and
the through hole is formed by abrading the plating undercoat layer over the projection portions prior to heating.

7. The resin protrusion forming method of claim 6, wherein each of the projection portions is configured with a tapered shape that narrows on progression towards a leading end.

8. The resin protrusion forming method of claim 1, wherein the retaining member is a photosensitive thermal curing resin, and the photosensitive thermal curing resin is cured by exposure to light prior to curing.

9. The resin protrusion forming method of claim 1, wherein the forming mold is pressed against the thermal curing resin layer to form a plurality of the protrusions in a state in which a viscosity of the thermal curing resin layer has been reduced.

10. The resin protrusion forming method of claim 1, wherein the retaining member continuously covers the protrusion and an inter-protrusion face.

11. A wiring board manufacturing method to manufacture a wiring board, the method comprising:
forming on a substrate a thermal curing resin layer that is in an uncured state;
forming a protrusion by pressing a forming mold against the thermal curing resin layer;
forming a retaining member that retains a side face of the protrusion;
heating the substrate on which the protrusion and the retaining member have been formed; and
forming wiring on the substrate whose protrusion has been heated by the heating at a portion where the protrusion is not formed.

12. The wiring board manufacturing method of claim 11, wherein the retaining member is a plating undercoat layer that forms an undercoat for plating of the protrusion and the substrate.

13. The wiring board manufacturing method of claim 12, wherein the plating undercoat layer is a single layer structure of the same material as the plating.

14. The wiring board manufacturing method of claim 12, wherein the plating undercoat layer includes a main component layer of the same material as the plating, and a close contact layer that places the main component layer in close contact with either the substrate or the thermal curing resin layer.

15. The wiring board manufacturing method of claim 12, wherein:
the retaining member is formed so as to cover the protrusion that is in the uncured state; and
a through hole is formed in the formed retaining member.

16. The wiring board manufacturing method of claim 15, wherein:
the protrusion is configured with a plurality of projection portions formed by pressing the forming mold, which is formed with a plurality of fine recesses, against the thermal curing resin layer; and
the through hole is formed by abrading the plating undercoat layer over the projection portions prior to heating.

17. The wiring board manufacturing method of claim 16, wherein each of the projection portions is configured with a tapered shape that narrows on progression towards a leading end.

18. The wiring board manufacturing method of claim 11, wherein the retaining member is a photosensitive thermal curing resin, and the photosensitive thermal curing resin is cured by exposure to light prior to curing.

19. The wiring board manufacturing method of claim 11, wherein the forming mold is pressed against the thermal curing resin layer to form a plurality of the protrusions in a state in which a viscosity of the thermal curing resin layer has been reduced.

20. The wiring board manufacturing method of claim 11, wherein the retaining member continuously covers the protrusion and an inter-protrusion face.
